(19) United States
(12) Patent Application Publication
(10) Pub. No.: US 2006/0280964 A1
(43) Pub. Date: Dec. 14, 2006

(54) Light-emitting device

(75) Inventor: Zugang Liu, Oxford (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: CDT OXFORD LTD., Cambridgeshire (GB)

(21) Appl. No.: 11/436,425

(22) Filed: May 18, 2006

(30) Foreign Application Priority Data
May 19, 2005 (GB) 0510244.7

(51) Int. Cl. H01L 51/50; H01L 51/56; H05B 33/12

(52) U.S. Cl. 428/690; 428/917; 427/66; 438/35; 313/504; 313/506; 257/89; 257/E51.022

(57) ABSTRACT

A full colour optical device comprising: an anode; a cathode; a light-emitting region located between the anode and the cathode; characterised in that said light-emitting region comprises subpixels of blue, green and red emitting materials, the blue emitting material being fluorescent and at least one of the green and red emitting materials being phosphorescent, wherein the cathode injects electrons into each subpixel and the cathode comprises: a first layer comprising a compound of a group 1, group 2 or transition metal; and a second layer comprising a material having a work function below 3.5 eV.

### BACKGROUND OF THE INVENTION

1. Field of the Invention

The invention relates to a full color optical device and to a method of making the same.

2. Related Technology

Luminescent conjugated polymers are a new technologically important class of materials that will be used in optical devices for the next generation of information technology based consumer products. The principle interest in the use of polymers, as opposed to inorganic semiconducting and organic dye materials, lies in the scope for low-cost manufacturing, using solution-processing of film-forming materials. Since the last decade much effort has been devoted to the improvement of the emission efficiency of organic light emitting diodes (OLEDs) either by developing highly efficient materials or efficient device structures.

In organic light-emitting devices (OLEDs), electrons and holes are injected from opposite electrodes and are combined to form two types of excitons; spin-symmetric triplets and spin-antisymmetric singlets in a theoretical ratio of 3:1. Radiative decay from the singlets is fast (fluorescence), but from the triplets (phosphorescence) it is formally forbidden by the requirement of the spin conservation.

Initially spurred on by this understanding that the maximum internal quantum efficiency of a fluorescent OLED was limited to 25% the idea of transferring both singlets and triplets to a phosphorescent dopant was conceived. Such a phosphorescent dopant typically is able to accept both singlet and triplet excitons from the organic material and generate luminescence, particularly electroluminescence from both.

In the past few years many have studied the incorporation by blending of phosphorescent materials into a semiconductive layer. In the last decade, much effort has been devoted to the improvement of the emission efficiency of light-emitting devices (LEDs) either by developing highly efficient materials or efficient device structures.

FIG. 1 shows cross-section of a typical OLED. The device has a substrate 1, an anode 2, a cathode 4 and a light emissive layer 3 located between the anode and the cathode. The anode may be, for example, a layer of transparent indium tin oxide. Holes and electrons that are injected into the device recombine radiatively in the light emissive layer. A further feature of the device is the optional hole injection layer between the anode and the light-emissive layer. The hole injection layer may be a conductive layer of polyethylene dioxythiophene (PEDOT) for example. This provides an energy level which helps the holes injected from the anode to reach the light emissive layer.

Known OLED structures also may have an electron and/or hole transport layer. This provides an energy level which helps the electrons injected from the cathode and/or holes injected from the anode to reach the light emissive layer.

One feature of OLED architecture that has attracted considerable research is the selection of the cathode. A variety of cathode configurations have been proposed. For example, WO 00/48258 discloses an opto-electrical device having a cathode electrode including a first layer comprising a compound of group 1, group 2, or a transition metal; a second layer comprising a material having a workfunction below 3.5 eV; and a third layer having a workfunction above 3.5 eV.

Journal of Polymer Science Part B, Polymer Physics, Vol. 41, pp 2716-2725 (2003) demonstrates that cathode choice can have a dramatic impact on the performance of polymeric OLEDs based on a PVK (non-conjugated) host doped with the phosphorescent green emitter Ir(ppy)₃. Cathodes consisting of a thin layer of LiF or CsF salt backed by MgAg, Al or Ca/Al are mentioned.

Advanced Materials 2004, 16 No. 6 pp557 to 560 discloses solution-processable red phosphorescent dendrimers for light-emitting device applications. The device structure is glass/ITO/dendrimer:CBP/TPBI/LiF/Ca/Al.

Organic Electronics 4 (2003) 71-76 is concerned with the influence of molecular structure on the properties of dendrimer light-emitting diodes. The green-emitting dendrimers studied have an Ir(ppy)₃ core. Bilayer devices were fabricated with the structure ITO/dendrimer:CBP/TPBI/LiF/Ca/Al.

A full color optical device comprises display pixels and each pixel is divided into three subpixels, each emitting one of the three primary display colors (red, green and blue). Various methods are known for producing full color optical devices. Generally, these involve deposition of the red, green and blue electroluminescent materials into wells.

It is desirable for deposition to be carried out by solution processing, for example by ink jet printing.

WO2004/023574 provides a method for the production of full-color subpixellated organic electroluminescent devices. Substrates used in the method comprise wells wherein the walls of the wells do not require surface treatment prior to deposition of the electroluminescent material.

A full color display requires a cathode capable of injecting electrons into all three emissive materials, i.e. a common cathode for the red, green and blue electroluminescent materials. This has proven to be challenging in terms of achieving suitable device performance (e.g. lifetime and efficiency).

WO2004/084260 states that selection of the cathode is further complicated when the cathode is required to be compatible with all three of the red, green and blue electroluminescent materials as per a full color display. It is said that Synthetic Metals 111-112 (2000), 125-128 discloses a full color display wherein the cathode is LiF/Ca/Al. However, it is further said that whilst this cathode is particularly efficacious with respect to the blue emissive material it shows poor performance with respect to green and, especially, red emitters. For this cathode, the authors of WO2004/084260 state that they have found a particular problem of degradation in green and red efficiency when pixels of these colors are not driven which is believed to be due to migration of lithium into the electroluminescent material. WO2004/084260 is directed to a barium cathode in combination with a hole transporting layer for increasing lifetime and efficiency across the range of colors.

Accordingly, there is a desire to provide a full color optical device with suitable device performance.

### GENERAL DESCRIPTION OF THE INVENTION

The invention aims to at least partially address this need by providing a new full color optical device.

As such, a first aspect of the present invention provides a full color optical device comprising:

an anode;

a cathode;

a light-emitting region located between the anode and the cathode;

wherein the light-emitting region comprises subpixels of blue, green and red emitting materials, the blue emitting material being fluorescent and at least one of the green and red emitting materials being phosphorescent; wherein the cathode injects electrons into each subpixel and said cathode comprises:

a first layer comprising a compound of a group 1, group 2 or transition metal; and

a second layer comprising a material having a work function below 3.5 eV.

Preferably the red emitting material is phosphorescent.

When the red emitting material is phosphorescent, contrary to WO2004/084260, problems of degradation in red efficiency believed to be due to migration of lithium into the electroluminescent material are not observed in the present device. Instead, the present full color device having the specified cathode and a combination of a fluorescent blue emitting material and a phosphorescent red emitting material has been found to result in a device having improved lifetime.

The compound in the first layer is preferably a compound of a group 1 metal, such as lithium. The compound may, for example, be any of a halide (e.g. a fluoride), an oxide, a carbide or a nitride. Some of these compounds may be electrically conductive, others may be electrically insulating. The compound may be a complex of a group 1, group 2 or transition metal, especially an organic complex. The compound may be LiF.

The first layer may be spaced from the light-emitting region by the second layer. Alternatively the second layer may be spaced from the light-emitting region by the first layer. The closer of the first and second layers to the light-emitting region is preferably adjacent that region or there may be one or more further layers between the first layer and the light-emitting region. The further layer may be selected from a semiconductive electron transport layer and an electrically conductive electron injection layer.

The second layer suitably comprises a metal selected from the group comprising: Li, Ba, Mg, Ca, Ce, Cs, Eu, Rb, K, Y, Sm, Na, Sm, Sr, Tb or Yb, or an alloy of two or more of those metals; or an alloy or one or more of those metals with another metal such as Al, Zr, Si, Sb, Sn, Zn, Mn, Ti, Cu, Co, W, Pb, In or Ag. The second layer preferably comprises Ca. The second layer may consist essentially of Ca.

The thickness of the first layer is preferably in the range 0.6 to 6 nm, preferably about 2 nm. The thickness of the second layer is preferably up to 10 nm, and preferably about 5 nm.

The first layer preferably comprises more than 80%, more than 90%, more than 95% or most preferably more than 99% of the compound. The first layer preferably consists essentially of the said compound. The said compound may have an effective work function in the device of less than 3.5 eV.

The material of which the second layer is comprised preferably has a work function of less than 3.5 eV, less than 3.4 eV, or less than 3.3 eV or less than 3.2 eV or less than 3.1 eV or less than 3.0 eV. The second layer preferably comprises more than 80%, more than 90%, more than 95% or most preferably more than 99% of that material. The second layer preferably consists essentially of that material.

Optionally, the cathode includes a third layer spaced from the light-emitting region by the first and second layers and having a work function above 3.5 eV.

The third layer suitably comprises a material (a “higher work function material”) having a higher work function than those of the first and second cathode layers. The work function of the higher work function material is preferably greater than 4.0 eV. The higher work function material is suitably a metal. The higher work function material and/or the third layer itself preferably has an electrical conductivity greater than 10⁵ (ohms·cm)⁻¹. The higher work function material is preferably Al, Cu, Ag, Au or Pt; or an alloy of two or more of those metals; or an alloy of one or more of those metals together with another metal, or an oxide such as tin oxide or indium-tin oxide. More preferable, the higher work function material is Al. The thickness of the third layer is preferably 100 nm or more, preferably about 250 nm.

The second layer is preferably adjacent to the first layer. The third layer is preferably adjacent to the second layer. Alternatively, the cathode may comprise further layers located between the first, second and/or third layers. The cathode is preferably inorganic, most preferably metallic.

One of the electrodes is preferably light-transmissive, and most preferably transparent. This is preferably but not necessarily the anode electrode, which could be formed of tin oxide (TO), indium-tin oxide (ITO) or gold.

Turning to the blue, green and red emitting materials comprised in the subpixels, these may be any suitable materials provided that the blue emitting material is fluorescent and at least one of the green and red emitting materials is phosphorescent. The red emitting material preferably is phosphorescent.

By “red emitting material” is meant an organic material that by electroluminescence emits radiation having a wavelength in the range of 600-750 nm, preferably 600-700 nm, more preferably 610-650 nm and most preferably having an emission peak around 650-660 nm.

By “green emitting material” is meant an organic material that by electroluminescence emits radiation having a wavelength in the range of 510-580 nm, preferably 510-570 nm.

By “blue emitting material” is meant an organic material that by electroluminescence emits radiation having a wavelength in the range of 400-500 nm, more preferably 430-500 nm.

The thickness of the light-emitting region may be in the range of from 40 to 100 nm, preferably from 60 to 95 nm.

Optionally, the red, green, and blue emitting materials are blended with hole and/or electron transporting materials as disclosed, for example, in WO 99/48160. The red, green and/or blue emitting material may be covalently bound to a charge transport material.

Preferably, when the red emitting material is phosphorescent, it comprises a phosphorescent dendrimer comprising a core, and one or more conjugated dendrons comprising surface groups. However, this is not essential and a phosphorescent red emitting material may comprise a red phosphorescent small molecule, for example a metal (M) surrounded by three bidentate ligands, or a red phosphorescent linear polymer.

The solution processability of dendrimers is extremely adaptable as the surface groups that the control the processing properties can be modified independently of the light emitting core.

A phosphorescent red emitting material may comprise a metal complex. Preferred metal complexes comprise optionally substituted complexes of formula (1):
ML¹_{q} L²ᵣ L³ₛ (1)
wherein M is a metal; each of L¹, L² and L³ is a coordinating group; q is an integer; r and s are each independently 0 or an integer; and the sum of (a·q)+(b·r)+(c·s) is equal to the number of coordination sites available on M, wherein a is the number of coordination sites on L¹, b is the number of coordination sites on L² and c is the number of coordination sites on L³.

A phosphorescent red emitting material may have formula (2) or (3): 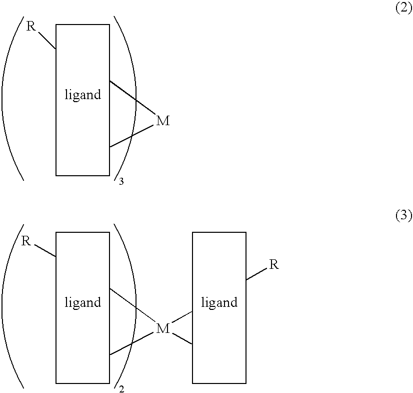
where M represents a metal and R represents H, a substituent group, or a dendron comprising a surface group.

When the red phosphorescent material is a small molecule, R represents H or a substituent group. Examples of substituent groups include solubilizing groups such as C₁₋₂₀ alkyl or alkoxy; electron withdrawing groups such as fluorine, nitro or cyano; and substituents for increasing glass transition temperature (Tg) of the polymer.

R may represent a dendron having a surface group such that the red emitting material is a dendrimer.

Preferably, the red phosphorescent dendrimer has formula (4) or (5) 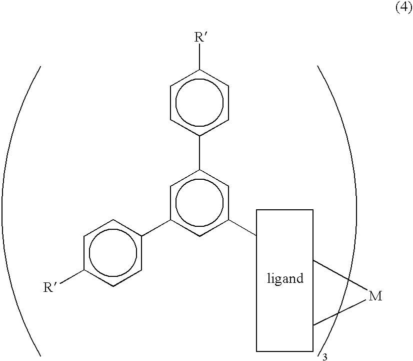 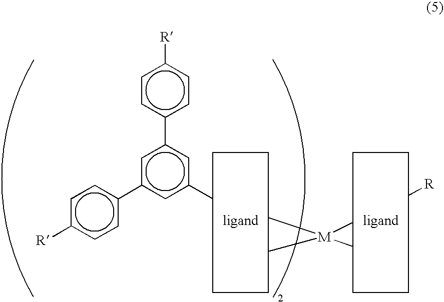
where M and R are as defined above and R′ represents H or a surface group.

Examples of surface groups R′ include solubilizing groups such as C₁₋₂₀ alkyl or alkoxy; electron withdrawing groups such as fluorine, nitro or cyano; and substituents for increasing glass transition temperature (Tg) of the polymer.

Preferably, R′ represents an alkyl or alkoxy group, preferably C1 to C20 alkyl or alkoxy, more preferably.

M may represent any suitable metal, in particular a d-block metal such as those in rows two and three i.e. elements 39 to 48 and 72 to 80, in particular ruthenium, rhodium, palladium, rhenium, osmium, iridium, platinum, tungsten and gold. Preferably, M represents iridium (Ir).

“Ligand” or “L” in formulae 1 to 5 may represent a carbon or nitrogen donor such as porphyrin or a bidentate ligand of formula (6): 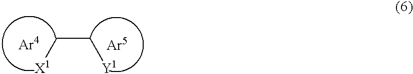
wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

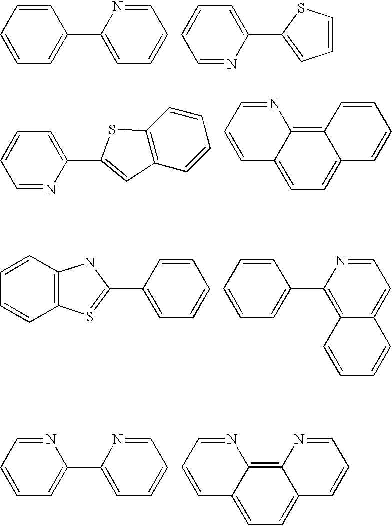

Each of Ar⁴ and Ar⁵ may carry one or more substituents. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

Other ligands suitable for use with d-block elements include diketonates, in particular acetylacetonate (acac); triarylphosphines and pyridine, each of which may be substituted.

The red phosphorescent dendrimer may have formula (7) or (8): 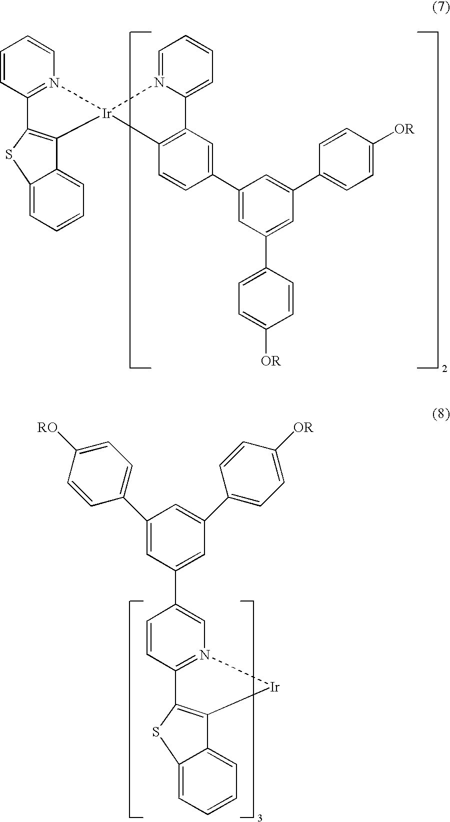
where R=2-ethyl, hexyl.

Any suitable host material may be used with the red phosphorescent material. The host material may be a small molecule or a polymer. It is preferred that the host material is a polymer, more preferably a conjugated polymer.

The concentration of the red emitting material in the polymer host may be sufficient so that emission from the polymer host is not visible. The concentration of the red emitting material in the polymer host may be greater that 7.5 wt %. The concentration of the red emitting material in the polymer host may be at least 10 wt %.

The concentration of the red emitting material in the polymer host may be sufficient so that emission from the polymer host is visible.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

Numerous hosts are described in the prior art including “small molecule” hosts such as 4,4′-bis(carbazol-9-yl)biphenyl), known as CBP, and (4,4′,4″-tris(carbazol-9-yl)triphenylamine), known as TCTA, disclosed in Ikai et al. (Appl. Phys. Lett., 79 no. 2, 2001, 156); and triarylamines such as tris-4-(N-3-methylphenyl-N-phenyl)phenylamine, known as MTDATA. Homopolymers are also known as hosts, in particular poly(vinyl carbazole) disclosed in, for example, Appl. Phys. Lett. 2000, 77(15), 2280; polyfluorenes in Synth. Met. 2001, 116, 379, Phys. Rev. B 2001, 63, 235206 and Appl. Phys. Lett. 2003, 82(7), 1006; poly[4-(N-4-vinylbenzyloxyethyl,N-methylamino)-N-(2,5-di-tert butylphenylnapthalimide] in Adv. Mater. 1999, 11(4), 285; and poly(para-phenylenes) in J. Mater. Chem. 2003, 13, 50-55.

A range of fluorescent blue emitting materials are known in the art. The fluorescent blue emitting material may comprise a conjugated semiconductive polymer. The conjugated semiconductive polymer may be a copolymer comprising two or more different repeat units. The conjugated polymer may be a linear polymer or branched polymer. The conjugated polymer may comprise one or more different aryl or heteroaryl repeat units.

An example of a blue fluorescent polymer is a copolymer comprising an optionally substituted arylene or heteroarylene repeat unit, for example fluorene, indenofluorene or spirobifluorene, and an optionally substituted triarylamine repeat unit, for example a repeat unit of formula (9): 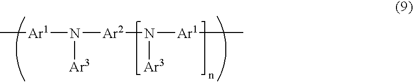
where n=0 or 1 and Ar¹, Ar² and Ar³ each independently represent a substituted or unsubstituted aryl or heteroaryl group.

Preferably, Ar¹ is phenylene.

Preferably, n is 0.

Preferably, Ar² is 1,4-phenylene or 4,4′-biphenylene.

When n is 0, Ar² is preferably 1,4-phenylene. When n is 1, Ar² is preferably 1,4-phenylene or 4,4′-biphenylene.

Preferably, Ar³ is phenyl. Ar³ may be substituted or unsubstituted; preferably Ar³ is substituted with a solubilizing group, more preferably optionally substituted C₁₋₂₀ alkyl or C₁₋₂₀ alkoxy.

Additional repeat units, such as hole or electron transporting repeat units, may also be present in the blue fluorescent polymer. Blue fluorescent polymers of this type are disclosed in, for example, WO 02/092723.

The fluorescent blue emitting material may comprise a metal complex.

The fluorescent blue emitting material may be a small molecule.

Green emitting materials also are known in the art.

A green emitting material may comprise a conjugated semiconductive polymer. The conjugated semiconductive polymer may be a copolymer comprising two or more different repeat units. The conjugated polymer may be a linear polymer or branched polymer. The polymer may be fluorescent. The conjugated polymer may comprise one or more different aryl or heteroaryl repeat units.

An example of a green fluorescent polymer is a copolymer comprising an optionally substituted arylene or heteroarylene repeat unit, for example fluorene, indenofluorene or spirobifluorene, and an optionally substituted 4,7-linked 2,1,3 benzothiadiazole repeat unit as disclosed in, for example, Macromolecules 2002, 35, 6094-6100. Additional repeat units, such as hole or electron transporting repeat units, may also be present in the green fluorescent polymer.

The green emitting material may comprise a metal complex. The metal complex may be phosphorescent.

The green emitting material may be a small molecule.

Preferred green fluorescent, green phosphorescent, and blue fluorescent metal complexes comprise optionally substituted complexes of formula (1) as defined above. Green fluorescent, green phosphorescent, and blue fluorescent metal complexes may be obtained by appropriate selection of M, L¹, L² and L³.

M may represent a heavy element. Heavy elements M induce strong spin-orbit coupling to allow rapid intersystem crossing and emission from triplet states (phosphorescence). Suitable heavy metals M include:
lanthanide metals such as cerium, samarium, europium, terbium, dysprosium, thulium, erbium and neodymium; and
d-block metals, in particular those in rows 2 and 3 i.e. elements 39 to 48 and 72 to 80, in particular ruthenium, rhodium, palladium, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission color is determined by the choice of the metal. The sharp emission is generally narrow, resulting in a pure color emission useful for display applications.

The d-block metals form organometallic complexes with carbon or nitrogen donors such as porphyrin or bidentate ligands of formula (6) as defined above.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission color is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014], in particular tris-(8-hydroxyquinoline)aluminium. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission color.

Optionally, a conductive organic hole injection layer is present between the anode and the light-emitting region.

The conductive organic hole injection layer comprises a conductive organic hole injection material. Preferably, the conductive organic hole injection material comprises doped polythiophene, more preferably doped poly(ethylene dioxythiophene), more preferably poly(ethylene dioxythiophene) doped with poly(styrene sulfonate) as disclosed in EP 0901176 and EP 0947123, or polyaniline as disclosed in U.S. Pat. No. 5,723,873 and U.S. Pat. No. 5,798,170.

The thickness of the hole injection layer is suitably around 50 nm.

Optionally, a semiconductive hole transport layer is present between the anode and the light-emitting region. When a conductive organic hole injection layer is present, the semiconductive hole transport layer is located between the conductive organic hole injection layer and the light-emitting region.

If present, a hole transporting layer preferably has a HOMO level of less than or equal to 5.5 eV, more preferably around 4.8-5.5 eV. If present, an electron transporting layer located between the light-emitting region and the cathode preferably has a LUMO level of around 3-3.5 eV.

The hole transport layer comprises a semiconductive hole transport material. The hole transport material may be cross-linked.

The hole transport material may substantially not be cross-linked. The hole transport material may be cured.

Preferably, the hole transport material is a polymer, more preferably a conjugated polymer.

Preferably, the hole transport polymer comprises an optionally substituted triarylamine repeat unit.

Preferably, the triarylamine repeat unit comprises an optionally substituted first repeat unit of formula (9) above. Preferably, Ar¹ is phenylene. Preferably, n is 0.

Preferably, Ar² is 1,4-phenylene or 4,4′-biphenylene. When n is 0, Ar² is preferably 1,4-phenylene. When n is 1, Ar² is preferably 1,4-phenylene or 4,4′-biphenylene.

Preferably, Ar³ is phenyl. Ar³ may be substituted or unsubstituted; preferably Ar³ is substituted with a solubilizing group, more preferably optionally substituted C₁₋₂₀ alkyl or C₁₋₂₀ alkoxy.

Preferably, the hole transport polymer is a copolymer comprising two or more repeat units. Preferably, one of the repeat units of such a copolymer is a first repeat unit of formula (9). More preferably, the copolymer comprises a second repeat unit selected from optionally substituted fluorene, indenofluorene, spirofluorene and phenylene.

The hole transport layer may contain a mixed layer comprising hole transport material and material from the layer on top of the hole transport layer (e.g. emissive material). Preferably, the mixed layer has a concentration gradient across its thickness. The concentration of hole transport material decreases with distance from the anode.

Preferably, the hole transport layer has a thickness in the range of from 10 to 50 nm, more preferably 15 to 25 nm, most preferably about 20 nm.

Optionally, an electron transport layer is present between the cathode and the light-emitting region. However, it is preferred that no electron transport layer is present and that the cathode is in direct contact with the light-emitting region.

A second aspect of the invention provides a method of making a device as defined in relation to the first aspect.

The first and second layers, and the third layer when present, of the cathode may be deposited by successive thermal evaporation steps, preferably in vacuo and preferably at a base pressure of less than 10-8 mbar.

The red, green and blue emitting materials may be deposited from solution. The solvent used for such a solution may be a common organic solvent, such as toluene or xylene.

The red, green and blue emitting materials may be deposited by ink jet printing.

The red, green and blue emitting materials may be deposited into wells, for example by ink jet printing, to form corresponding red, green and blue subpixels. The wells may be formed by photolithography.

Preferably, the hole transport layer is deposited from solution. The solvent used for such a solution may be the same as or different to the solvent used to deposit the next layer of the device onto the hole transport layer.

The hole transport layer may be treated after deposition in order to render it insoluble in the solvent used to deposit the next layer of the device onto the hole transport layer. The layer of the device deposited onto the hole transport layer typically comprises the light-emitting region.

In one embodiment, the hole transport material comprises cross-linking groups and the treatment comprises subjecting the hole transport layer to heat or electromagnetic radiation, in particular UV radiation, in order to crosslink the hole transporting material.

The hole transporting layer may be rendered insoluble in the solvent even when cross-linking groups are absent. Accordingly, in another embodiment, the hole transporting layer is substantially free of cross-linking groups and the treatment comprises curing by subjecting the hole transport layer to heat.

Following the aforementioned treatment, it may be possible to solubilize the hole transport layer under forcing conditions (e.g. by exposure to the solvent at elevated temperature and/or immersion in the solvent over a prolonged period), particularly in the case where the hole transport layer is substantially free of cross-linking groups. In the context of the invention, rendering the hole transport layer insoluble in the solvent means that at least part of the hole transport layer remains intact under conditions typically employed for deposition of the next layer of the device onto the hole transport layer, although an upper part of the hole transport layer may dissolve upon contact with the solvent.

In fact, partial dissolution of the hole transport layer may be desirable in order to form a mixed layer between the hole transport layer and the next layer of the device deposited onto the hole transport layer. The extent of this partial dissolution may be controlled by appropriate selection of conditions for insolubilization of the hole transport layer. Thus, the use of cross-linking groups will typically result insolubilization of the whole of the hole transport layer as deposited. Alternatively, selection of time and temperature for heat treatment of a hole transport layer that is substantially free of cross-linking groups may be used to control the extent of insolubilization of the hole transport layer as deposited.

The hole transport material may be deposited in a composition comprising the hole transport material and the material which will form the next layer of the device. After deposition, the composition may be phase separate during evaporation of the solvent such that the hole transport material migrates towards the anode. The phase separation of the hole transport material may result in a mixed layer as described above.

### BRIEF DESCRIPTION OF THE DRAWINGS

The invention will now be described by way of example with reference to the accompanying drawings, in which:

FIG. 1 shows a cross-section of a typical OLED.

FIG. 2 is a cross-section of a light-emissive device;

FIG. 3 shows the device structure of Example 1;

FIG. 4 shows the CIE coordinates of the dendrimer and small molecule phosphorescence in Example 1;

FIG. 5 shows the emission spectra of, the dendrimer and small molecule phosphorescence in Example 1;

FIG. 6 shows the variation of efficiency with brightness in Example 2;

FIG. 7 shows results from Example 3.

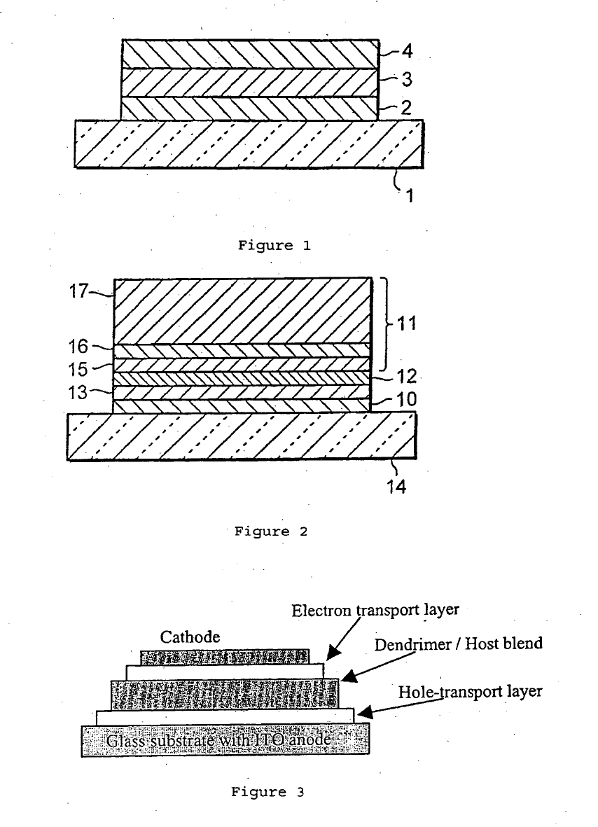

### DETAILED DESCRIPTION

The device of FIG. 2 comprises an anode electrode 10 and a cathode electrode 11. Located between the electrode layers is an active layer 12 of light-emissive material. A hole injection layer 13 of PEDOT: PSS is located between the anode electrode 10 and the light-emissive layer 12. The device is formed on a glass substrate 14.

The metallic cathode 11 comprises three layers. Next to the emissive layer 12 is a first layer 15, of lithium fluoride. Over that is a second layer 16, of calcium. Over that is a third layer 17, of aluminium.

To form the device of FIG. 2 a transparent layer of ITO to form the anode electrode 10 may first be deposited on a sheet of glass 14. The glass sheet could be a sheet of soda lime or borosilicate glass of a thickness of, for instance, 1 mm.

The thickness of the ITO coating is suitably around 100 to 150 nm and the ITO D suitably has a sheet resistance of between 10 and 30 ohms/□. ITO-coated glass substrates of this type are commercially available. As an alternative to glass, the sheet 14 could be formed of Perspex. As an alternative to ITO, gold or TO could be used as the anode.

On the ITO anode, wells are formed by photolithography.

First, a hole injection layer 13 is ink jet printed into the wells. The hole injection layer is formed from a solution containing PEDOT: PSS available from H C Starck under the trade name BAYTRON P™. The thickness of the hole injection layer is suitably around 50 nm. The hole injection layer is then baked at around 200° C. for 1 hour in a nitrogen environment.

A hole transport layer is ink jet printed into the wells over the hole injection layer 13.

Then the light-emissive layer 15 is deposited by ink jet printing into the wells.

The cathode is then deposited. The three distinct layers of the cathode are deposited by successive thermal evaporation steps in vacuo at a base pressure of less than 10-8 mbar. Preferably the vacuum is not broken between the successive steps, to reduce the possibility of contamination of the interfaces between the layers. One alternative to thermal evaporation is sputtering, but this is less preferred for at least the deposition of the layer 15 adjacent to the emissive layer since it may cause damage to the emissive layer 12. In the first thermal evaporation step the layer 15 is deposited. The layer 15 is of lithium fluoride and has a thickness of approximately 0.6 to 6 nm, preferably about 2 nm. In the second thermal evaporation step the layer 16 is deposited. The layer 16 is of calcium and has a thickness of up to 10 nm, preferably about 5 nm. In the third thermal evaporation step the layer 17 is deposited. The layer 17 is of aluminium and has a thickness of 100 nm or more, preferably about 250 nm.

Finally, contacts are attached to the layers 10 and 17 and, although the aluminium layer 16 may act to some extent as an encapsulant, the device is preferably sealed in epoxy resin for environmental protection.

When a suitable voltage is applied between the anode and the cathode the light-emissive layer is stimulated to emit light. This passes to a viewer through the transparent anode and the glass cover sheet.

### EXAMPLE 1

Device structure as shown in FIG. 3 was constructed in order to demonstrate the suitability of a LiF/Ca cathode for use with a red phosphorescent dendrimer I. The corresponding device was constructed using solubilized red phosphorescent small molecule II.

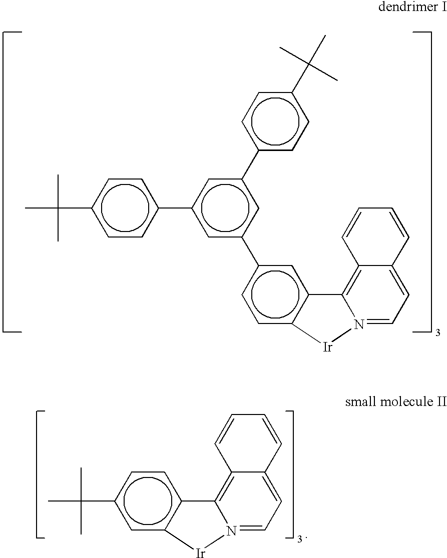

CBP was used as the host material.

Results are shown in Table 1.

It can clearly be seen that both of the emitters give a red color that is very close to the desired PAL standard for red emission.

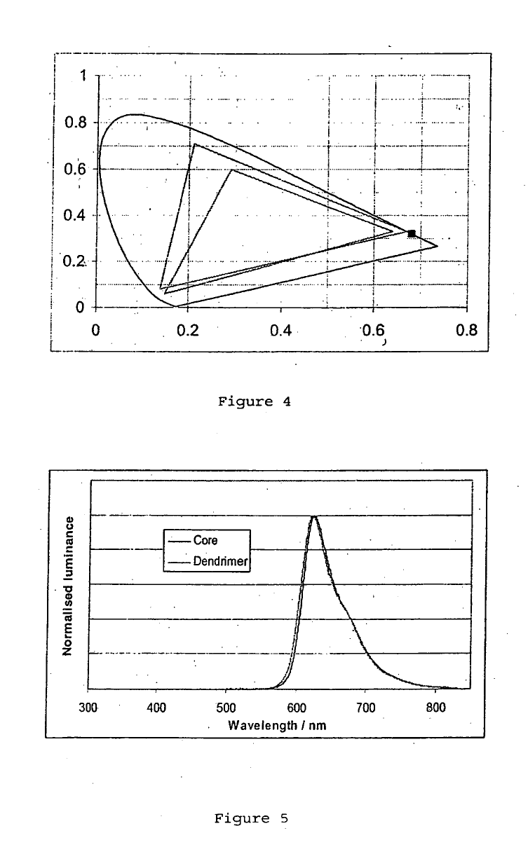

This can be seen in the CIE chart shown in FIG. 4, and in the emission spectra of both compounds shown in FIG. 5. It is clear that attaching the dendrons has no significant effect on the emission spectrum of the core.

TABLE 1
Device comparison of Dendrimer and Small Molecule in Molecular Host

| | | | Cd/A at | lm/W at | Lifetime |
|---|---|---|---|---|---|
| | | | 100 | 100 | at 800 |
| | CIE-x | CIE-y | cd/m² | cd/m² | cd/m² |
| Small | 0.68 | 0.31 | 7.53 | 3.84 | 200 |
| molecule | | | | | |
| Dendrimer | 0.68 | 0.32 | 5.77 | 2.27 | 740 |

Both devices were made with an unoptimized 10 wt % concentration of the emitter, which is likely to explain the minor variations in efficiency—both compounds still gave good cd/A efficiencies. This is as expected, as the solution photoluminescence quantum efficiencies of both of these compounds are the same at 60%. The voltages of the dendrimer devices are slightly higher, and hence the 1 m/W values are lower, but this is believed to be a factor of the lower concentration of the charge-transporting iridium centres in these devices.

What was most interesting about these devices was that the dendrimer gave a significantly longer lifetime than the small molecule. In conclusion, the dendritic structure increases the stability of the device.

### EXAMPLE 2

Example 1 was repeated using a polymeric host in place of CBP. The following device architecture was used in Example 2:

ITO/PEDOT:PSS/Polymer:Red Dendrimer/cathode

Three different cathodes were tested: barium, calcium and lithium fluoride/calcium.

By optimising the concentration of the dendrimer, the emission color was an excellent red: CIE (0.67, 0.32). Below a dendrimer concentration of 7.5 wt % some polymer emission was still visible, indicating that energy transfer from the polymer to the dendrimer was inefficient at these concentrations. A concentration of 10 wt % was used for subsequent experiments. Results are given in table 2 below.

TABLE 2

| | Emission | cd/A at | lm/W at | Lifetime |
|---|---|---|---|---|
| | layer | 100 | 100 | from 2000 |
| Cathode | thickness/nm | cd/m2 | cd/m2 | cd/m2 |
| Ba | 60 | 1.88 | 1.09 | 152 |
| Ba | 75 | 3.58 | 1.29 | 359 |
| Ca | 60 | 1.72 | 0.85 | 126 |
| Ca | 75 | 3.29 | 1.02 | 370 |
| LiF/Ca | 60 | 2.93 | 1.51 | 165 |
| LiF/Ca | 75 | 3.96 | 1.56 | 378 |

Thicker emission layers and changing from Ba or Ca to LiF/Ca all give higher efficiencies.

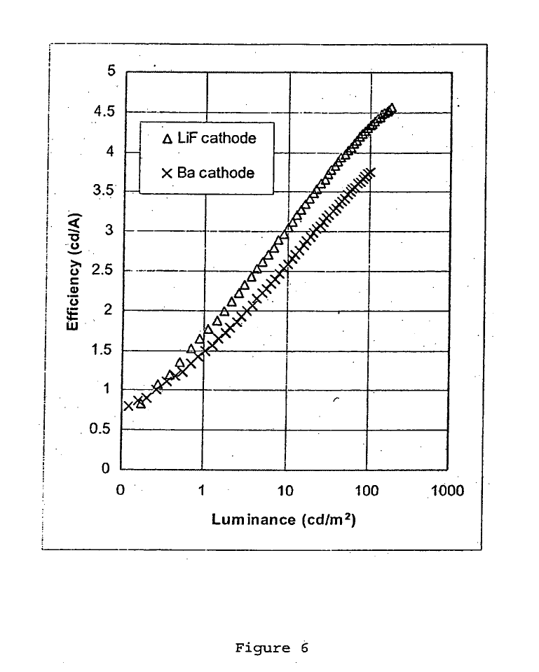

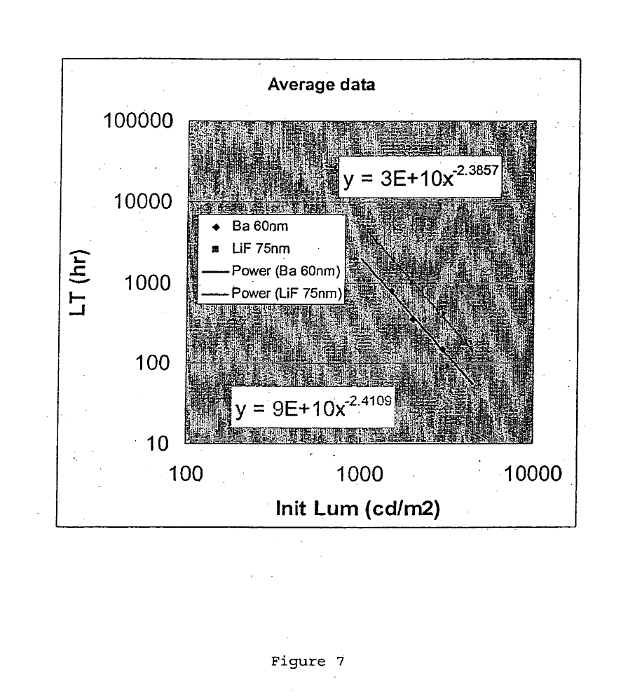

It is also significant to note that the devices are not at their maximum efficiency at 100 cd/m2 and that these maxima are actually reached at much higher brightness, as can be seen in FIG. 6.

The lifetimes of the dendrimer/polymer devices follow the standard exponential relationship seen with other conjugated polymer systems. With these materials, the acceleration factor is between 2.0-2.1, so lifetimes from 100 cd/m2 can be estimated from the values in table 2 by multiplying by (2000/100)ˆ2=400. This gives lifetimes in the range of 50,000 to 150,000 hours.

There is clearly a strong relationship between emission layer thickness and device lifetime, perhaps indicating that whatever process is quenching the emission is also significantly affecting the stability of the devices. The lifetimes from the polymer host are up to 10 times higher than those obtained for the molecular host.

### EXAMPLE 3

Example 2 was repeated but with a hole transport layer incorporated into the device. The device architecture was:

ITO/PEDOT/hole transport layer/polymeric host:dendrimer/Ba (Ca, LiF/Ca)/Al

The results are shown in Table 3.

| | Emission | | | | | | | | | | |
|---|---|---|---|---|---|---|---|---|---|---|---|
| | layer | | | V | Max | Cd/A | Lm/W | V@ | Cd/A | Lm/W | LT @ |
| Cathode | thickness/nm | CIE-x | CIE-y | (100 cd) | QE | (100 cd) | (100 cd) | 400 | @ 400 | @ 400 | 2000 |
| LiF/Ca | 60 | 0.670 | 0.318 | 4.69 | 4.10 | 2.93 | 1.96 | 5.00 | 3.07 | 1.93 | 424 |
| LiF/Ca | 75 | 0.677 | 0.317 | 7.01 | 6.64 | 3.96 | 1.76 | 7.57 | 4.21 | 1.73 | 978 |
| Ca | 60 | 0.665 | 0.318 | 5.66 | 2.85 | 1.59 | 0.89 | 6.02 | 1.80 | 0.94 | 298 |
| Ca | 75 | 0.676 | 0.317 | 8.51 | 4.30 | 2.86 | 1.05 | 8.67 | 3.25 | 1.18 | 865 |
| Ba | 60 | 0.668 | 0.318 | 5.09 | 3.61 | 2.37 | 1.46 | 5.43 | 2.54 | 1.46 | 352 |
| Ba | 75 | 0.677 | 0.316 | 7.76 | 5.82 | 3.53 | 1.42 | 8.26 | 3.76 | 1.41 | 770 |

### CONCLUSION

The more electrons injected into the light-emitting layer (EML), the higher efficiency and the longer the lifetime is. So LiF/Ca devices are with highest efficiency and longest lifetime.

The efficiency and lifetime of thicker EML devices are larger than thinner EML devices.

The longest lifetime is 1000 hours @ 2000 cd/m2, with an efficiency about 4 cd/A (100 cd/m2), over 5 cd/A @ 2000 cd/m2. Using the AF 2.4, the lifetime can be extrapolated to over 8,800 hrs @ 800 cd/m2, 47,000 hrs @ 400 cd/m2.

1. A full color optical device comprising:
an anode;
a cathode;
a light-emitting region located between the anode and the cathode;
wherein said light-emitting region comprises subpixels of blue, green, and red emitting materials, the blue emitting material being fluorescent and at least one of the green, and red emitting materials being phosphorescent, wherein the cathode injects electrons into each subpixel and the cathode comprises:
a first layer comprising a compound of a group 1 metal, group 2 metal or a transition metal; and
a second layer comprising a material having a work function below 3.5 eV.

2. A device according to claim 1, wherein the compound in the first layer is a compound of a group 1 metal.

3. A device according to claim 2, wherein the compound is lithium fluoride.

4. A device according to claim 1, wherein the second layer comprises a metal selected from the group consisting of Li, Ba, Mg, Ca, Ce, Cs, Eu, Rb, K, Y, Sm, Na, Sm, Sr, Tb, Yb, and alloys thereof.

5. A device according to claim 4, wherein the second layer consists essentially of Ca.

6. A device according to claim 1, wherein the cathode includes a third layer spaced from the light-emitting region by the first and second layers and having a work function above 3.5 eV.

7. A device according to claim 6, wherein the third layer comprises a metal selected from the group consisting of Al, Cu, Ag, Au, Pt, and alloys thereof.

8. A device according to claim 1, wherein the red emitting material is phosphorescent.

9. A device according to claim 8, wherein the phosphorescent red emitting material has formula (2) or (3): 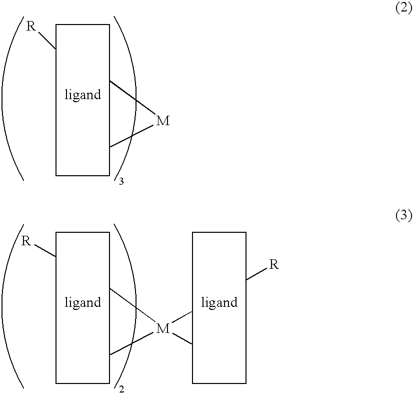
where M represents a metal and R represents H, a substituent group, or a dendron comprising a surface group.

10. A device according to claim 8, wherein the phosphorescent red emitting material comprises a dendrimer.

11. A device according to claim 10, wherein the dendrimer has formula (4) or (5): 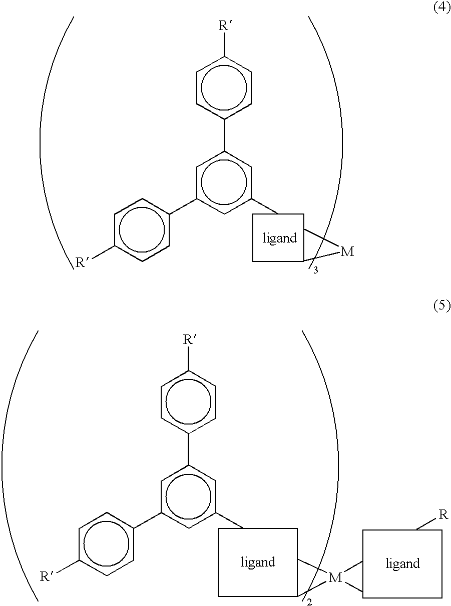
where M represents a metal, R represents H, a substituent group, or a dendron comprising a surface group, and R′ represents H or a surface group.

12. A device according to claim 8 comprising a host material used with the phosphorescent red emitting material, said host comprising a polymer.

13. A device according to claim 12, wherein the host polymer is a conjugated polymer.

14. A device according to claim 1, wherein the blue emitting material comprises a conjugated semiconductive polymer.

15. A device according to claim 1, comprising a conductive organic hole injection layer present between the anode and the light-emitting region.

16. A device according to claim 1, comprising a semiconductive hole transport layer present between the anode and the light-emitting region.

17. A device according to claim 16, wherein the hole transport layer comprises a semiconductive hole transport polymer.

18. A device according to claim 17, wherein the hole transport polymer is conjugated.

19. A device according to claim 17, wherein the hole transport polymer is cross-linked.

20. A device according to claim 17, wherein the hole transport polymer is cured.

21. A device according to claim 17, wherein the hole transport polymer comprises a triarylamine repeat unit.

22. A device according to claim 17, wherein the hole transport polymer further comprises a repeat unit selected from the group consisting of optionally substituted fluorene, indenofluorene, spirofluorene, and phenylene.

23. A method of making a device according to claim 1, comprising depositing the red, green, and blue emitting materials from solution.

24. A method according to claim 23, further including depositing a hole transport layer from solution.

25. A method according to claim 24, further including treating the hole transport layer after deposition in order to render it insoluble in the solvent used to deposit a next layer of the device onto the hole transport layer.

26. A method according to claim 23, further including depositing the first and second layers of the cathode, and optionally a third layer spaced from the light emitting region by the first and second layers and having a work function above 3.5 eV, by successive thermal evaporation steps.
